(19) United States
(12) Patent Application Publication
(10) Pub. No.: US 2020/0226487 A1
(43) Pub. Date: Jul. 16, 2020

(54) Measurement Reduction Via Orbital Frames Decompositions On Quantum Computers

(71) Applicant: Zapata Computing, Inc., Boston, MA (US)

(72) Inventors: Maxwell D. RADIN, Cambridge, MA (US); Peter D. JOHNSON, Somerville, MA (US)

(21) Appl. No.: 16/740,177

(22) Filed: Jan. 10, 2020

Related U.S. Application Data
(60) Provisional application No. 62/790,915, filed on Jan. 10, 2019.
(60) Provisional application No. 62/890,901, filed on Aug. 23, 2019.

(51) Int. Cl. G06N 10/00; G06F 17/18

(52) U.S. Cl. CPC G06N 10/00; G06F 17/18

(57) ABSTRACT

A hybrid quantum classical (HQC) computer, which includes both a classical computer component and a quantum computer component, implements improvements to expectation value estimation in quantum circuits, in which the number of shots to be performed in order to compute the estimation is reduced by applying a quantum circuit that imposes an orbital rotation to the quantum state during each shot instead of applying single-qubit context-selection gates. The orbital rotations are determined through the decomposition of a Hamiltonian or another objective function into a set of orbital frames. The variationally minimized expectation value of the Hamiltonian or the other objective function may then be used to determine the extent of an attribute of the system, such as the value of a property of the electronic structure of a molecule, chemical compound, or other extended system.

### BACKGROUND

Quantum computers promise to solve industry-critical problems which are otherwise unsolvable. Key application areas include chemistry and materials, bioscience and bioinformatics, logistics, and finance. Interest in quantum computing has recently surged, in part, due to a wave of advances in the performance of ready-to-use quantum computers.

A quantum computer can be used to calculate physical properties of molecules and chemical compounds. Some examples include the amount of heat released or absorbed during a chemical reaction, the rate at which a chemical reaction might occur, and the absorption spectrum of a molecule or chemical compound. Although such physical properties are commonly calculated on classical computers using ab initio quantum chemistry simulations, quantum computers hold the potential to enable these properties to be calculated more quickly and accurately. One prominent hybrid quantum/classical method for performing such calculations is the variational quantum eigensolver (VQE). In this approach, the quantum state of the qubits represents the quantum state of the electrons of a molecule or extended system (e.g., a crystalline solid or surface), and measurements performed on the qubits yield information about the physical properties of a molecule or extended system whose electrons are in the corresponding quantum state. Examples of approaches for mapping quantum states of a molecule or extended system to quantum states of a quantum computer include the Jordan-Wigner and Bravyi-Kitaev transformations.

The prototypical use of VQE is to calculate the ground state energy of a molecule or extended system. Given a wavefunction ansatz, the ground state energy can be estimated by varying the ansatz parameters so as to minimize the expectation value of the electronic structure Hamiltonian. The role of the quantum computer in the VQE approach is to evaluate the expectation value of the Hamiltonian with respect to a trial wavefunction during this minimization procedure. The conventional evaluation of this expectation value for a particular trial wavefunction is achieved by decomposing the transformed Hamiltonian into tensor products of Pauli operators acting on the qubits. The expectation value of each of these tensor products (i.e., Pauli terms) can be determined by repeatedly preparing the quantum computer in a state that corresponds to the trial wavefunction and measuring each qubit that the Pauli term acts on. The measurement context for each qubit is be chosen according to the Pauli term's action on that qubit. Pauli terms which do not have differing non-trivial action on any qubit can be measured simultaneously in this manner and are said to be qubit-wise co-measureable. Although they incur longer circuit depths, alternative Pauli-string co-measureability criteria, such as Pauli-string commutativity or Pauli-string anti-commutativity may be employed. These three Pauli-based grouping techniques serve to parallelize the individual procedures used to statistically estimate the expectation value of an operator. Pauli-based grouping methods construct component operators of the target Hamiltonian according to a Pauli-string compatibility criterion.

FIG. 4 shows a flowchart corresponding to the conventional VQE procedure. For each step in the optimization of the ansatz parameters, a plurality of groups of co-measurable Pauli terms are considered. For each group of co-measurable Pauli terms, a plurality of shots are performed on a quantum computer. Each shot includes the initialization of the qubits, the application of the ansatz circuit, the application of single-qubit gates for context selection, and the measurement of qubits.

FIG. 5 shows a schematic of a quantum circuit that is executed during a shot in this approach. The circuit begins with an ansatz circuit A that prepares a state corresponding to the trial wavefunction. This is followed by single-qubit gates that set the measurement context of individual qubits. At the end of the circuit, all qubits are measured. The context selection gates shown in FIG. 2 consist of Hadamard gates applied to the first, second, and fourth qubits so as to set the measurement context of these qubits to X. This choice of measurement context is a hypothetical example for illustrative purposes and bears no significance. Different measurement contexts, such as the standard X, Y, and Z contexts, may be achieved for each qubit by applying different single-qubit gates.

One challenge with the conventional approach described above is that the number of shots required in order to achieve a certain level of accuracy grows very rapidly with the number of orbitals in the problem. This arises from the fact that the decomposition of the Hamiltonian yields a large number of Pauli terms, many of which are not co-measurable. Therefore, it may take an exceedingly large amount of time to perform a VQE calculation using the conventional approach. The number of shots required for measuring the expectation value of the Hamiltonian is also a challenge for many variations and extensions of VQE (e.g., methods for calculating the energies of excited states).

A number of strategies have been proposed for reducing the number of shots required. This includes truncating the Hamiltonian by neglecting small terms (or evaluating small terms using a simplified classical model), as well as strategies for finding large co-measurable groups of Pauli terms. However, improved techniques for reducing the number of shots to be performed are needed in order to allow the VQE method to be practical on near-term quantum computers. Such improvements would have a wide variety of applications in chemistry, physics, and materials science.

### SUMMARY

A hybrid quantum classical (HQC) computer, which includes both a classical computer component and a quantum computer component, implements improvements to expectation value estimation in quantum circuits, in which the number of shots to be performed in order to compute the estimation is reduced by applying a quantum circuit that imposes an orbital rotation to the quantum state during each shot instead of applying single-qubit context-selection gates. The orbital rotations are determined through the decomposition of a Hamiltonian or another objective function into a set of orbital frames. The variationally minimized expectation value of the Hamiltonian or the other objective function may then be used to determine the extent of an attribute of the system, such as the value of a property of the electronic structure of a molecule, chemical compound, or other extended system.

It is to be understood that both the foregoing general description and the following detailed description are exemplary and explanatory only and are not restrictive of the invention, as claimed.

Other features and advantages of various aspects and embodiments of the present invention will become apparent from the following description and from the claims.

The accompanying drawings, which are incorporated in and constitute a part of this specification, illustrate one embodiment of the present invention and together with the description, serve to explain the principles of the invention.

### BRIEF DESCRIPTION OF THE DRAWINGS

FIG. 1 shows a diagram of a system implemented according to one embodiment of the present invention.

FIG. 2A shows a flow chart of a method performed by the system of FIG. 1 according to one embodiment of the present invention.

FIG. 2B shows a diagram illustrating operations typically performed by a computer system which implements quantum annealing.

FIG. 3 shows a diagram of a HQC computer system implemented according to one embodiment of the present invention.

FIG. 4 is a flowchart showing the conventional implementation of the variational quantum eigensolver (VQE) approach;

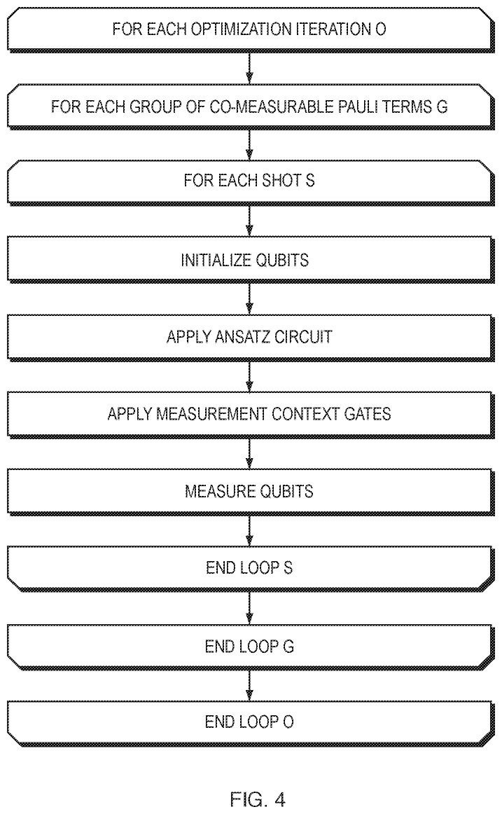

FIG. 5 is a schematic of a hypothetical quantum circuit used in the conventional VQE approach;

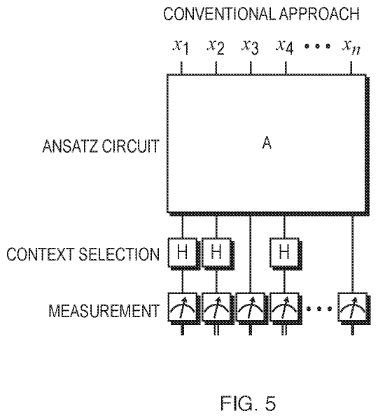

FIG. 6 is a flowchart showing the orbital-frames approach to VQE according to one embodiment of the present invention;

FIG. 7 is a schematic of a quantum circuit that may be used in the orbital-frames approach to VQE according to one embodiment of the present invention; and

FIG. 8 is a flowchart of a method performed by a hybrid quantum-classical (HQC) computer to compute an expectation value of a first operator according to one embodiment of the present invention.

### DETAILED DESCRIPTION

Embodiments of the present invention are directed to a hybrid quantum classical (HQC) computer, which includes both a classical computer component and a quantum computer component, and which implements a method for constructing a measurement module, wherein the measurement module is adapted to compute expectation values more efficiently than Pauli-based grouping.

It is to be understood that although the invention is here described in terms of particular embodiments, the embodiments disclosed herein are provided as illustrative only, and do not limit or define the scope of the invention. For example, elements and components described herein may be further divided into additional components or joined together to form fewer components for performing the same functions.

Various physical embodiments of a quantum computer are suitable for use according to the present disclosure. In general, the fundamental data storage unit in quantum computing is the quantum bit, or qubit. The qubit is a quantum-computing analog of a classical digital computer system bit. A classical bit is considered to occupy, at any given point in time, one of two possible states corresponding to the binary digits (bits) 0 or 1. By contrast, a qubit is implemented in hardware by a physical medium with quantum-mechanical characteristics. Such a medium, which physically instantiates a qubit, may be referred to herein as a “physical instantiation of a qubit,” a “physical embodiment of a qubit,” a “medium embodying a qubit,” or similar terms, or simply as a “qubit,” for ease of explanation. It should be understood, therefore, that references herein to “qubits” within descriptions of embodiments of the present invention refer to physical media which embody qubits.

Each qubit has an infinite number of different potential quantum-mechanical states. When the state of a qubit is physically measured, the measurement produces one of two different basis states resolved from the state of the qubit. Thus, a single qubit can represent a one, a zero, or any quantum superposition of those two qubit states; a pair of qubits can be in any quantum superposition of 4 orthogonal basis states; and three qubits can be in any superposition of 8 orthogonal basis states. The function that defines the quantum-mechanical states of a qubit is known as its wavefunction. The wavefunction also specifies the probability distribution of outcomes for a given measurement. A qubit, which has a quantum state of dimension two (i.e., has two orthogonal basis states), may be generalized to a d-dimensional “qudit,” where d may be any integral value, such as 2, 3, 4, or higher. In the general case of a qudit, measurement of the qudit produces one of d different basis states resolved from the state of the qudit. Any reference herein to a qubit should be understood to refer more generally to an d-dimensional qudit with any value of d.

Although certain descriptions of qubits herein may describe such qubits in terms of their mathematical properties, each such qubit may be implemented in a physical medium in any of a variety of different ways. Examples of such physical media include superconducting material, trapped ions, photons, optical cavities, individual electrons trapped within quantum dots, point defects in solids (e.g., phosphorus donors in silicon or nitrogen-vacancy centers in diamond), molecules (e.g., alanine, vanadium complexes), or aggregations of any of the foregoing that exhibit qubit behavior, that is, comprising quantum states and transitions therebetween that can be controllably induced or detected.

For any given medium that implements a qubit, any of a variety of properties of that medium may be chosen to implement the qubit. For example, if electrons are chosen to implement qubits, then the x component of its spin degree of freedom may be chosen as the property of such electrons to represent the states of such qubits. Alternatively, the y component, or the z component of the spin degree of freedom may be chosen as the property of such electrons to represent the state of such qubits. This is merely a specific example of the general feature that for any physical medium that is chosen to implement qubits, there may be multiple physical degrees of freedom (e.g., the x, y, and z components in the electron spin example) that may be chosen to represent 0 and 1. For any particular degree of freedom, the physical medium may controllably be put in a state of superposition, and measurements may then be taken in the chosen degree of freedom to obtain readouts of qubit values.

Certain implementations of quantum computers, referred as gate model quantum computers, comprise quantum gates. In contrast to classical gates, there is an infinite number of possible single-qubit quantum gates that change the state vector of a qubit. Changing the state of a qubit state vector typically is referred to as a single-qubit rotation, and may also be referred to herein as a state change or a single-qubit quantum-gate operation. A rotation, state change, or single-qubit quantum-gate operation may be represented mathematically by a unitary 2×2 matrix with complex elements. A rotation corresponds to a rotation of a qubit state within its Hilbert space, which may be conceptualized as a rotation of the Bloch sphere. (As is well-known to those having ordinary skill in the art, the Bloch sphere is a geometrical representation of the space of pure states of a qubit.) Multi-qubit gates alter the quantum state of a set of qubits. For example, two-qubit gates rotate the state of two qubits as a rotation in the four-dimensional Hilbert space of the two qubits. (As is well-known to those having ordinary skill in the art, a Hilbert space is an abstract vector space possessing the structure of an inner product that allows length and angle to be measured. Furthermore, Hilbert spaces are complete: there are enough limits in the space to allow the techniques of calculus to be used.)

A quantum circuit may be specified as a sequence of quantum gates. As described in more detail below, the term “quantum gate,” as used herein, refers to the application of a gate control signal (defined below) to one or more qubits to cause those qubits to undergo certain physical transformations and thereby to implement a logical gate operation. To conceptualize a quantum circuit, the matrices corresponding to the component quantum gates may be multiplied together in the order specified by the gate sequence to produce a 2ⁿ×2ⁿ complex matrix representing the same overall state change on n qubits. A quantum circuit may thus be expressed as a single resultant operator. However, designing a quantum circuit in terms of constituent gates allows the design to conform to a standard set of gates, and thus enable greater ease of deployment. A quantum circuit thus corresponds to a design for actions taken upon the physical components of a quantum computer.

A given variational quantum circuit may be parameterized in a suitable device-specific manner. More generally, the quantum gates making up a quantum circuit may have an associated plurality of tuning parameters. For example, in embodiments based on optical switching, tuning parameters may correspond to the angles of individual optical elements.

In certain embodiments of quantum circuits, the quantum circuit includes both one or more gates and one or more measurement operations. Quantum computers implemented using such quantum circuits are referred to herein as implementing “measurement feedback.” For example, a quantum computer implementing measurement feedback may execute the gates in a quantum circuit and then measure only a subset (i.e., fewer than all) of the qubits in the quantum computer, and then decide which gate(s) to execute next based on the outcome(s) of the measurement(s). In particular, the measurement(s) may indicate a degree of error in the gate operation(s), and the quantum computer may decide which gate(s) to execute next based on the degree of error. The quantum computer may then execute the gate(s) indicated by the decision. This process of executing gates, measuring a subset of the qubits, and then deciding which gate(s) to execute next may be repeated any number of times. Measurement feedback may be useful for performing quantum error correction, but is not limited to use in performing quantum error correction. For every quantum circuit, there is an error-corrected implementation of the circuit with or without measurement feedback.

Some embodiments described herein generate, measure, or utilize quantum states that approximate a target quantum state (e.g., a ground state of a Hamiltonian). As will be appreciated by those trained in the art, there are many ways to quantify how well a first quantum state “approximates” a second quantum state. In the following description, any concept or definition of approximation known in the art may be used without departing from the scope hereof. For example, when the first and second quantum states are represented as first and second vectors, respectively, the first quantum state approximates the second quantum state when an inner product between the first and second vectors (called the “fidelity” between the two quantum states) is greater than a predefined amount (typically labeled E). In this example, the fidelity quantifies how “close” or “similar” the first and second quantum states are to each other. The fidelity represents a probability that a measurement of the first quantum state will give the same result as if the measurement were performed on the second quantum state. Proximity between quantum states can also be quantified with a distance measure, such as a Euclidean norm, a Hamming distance, or another type of norm known in the art. Proximity between quantum states can also be defined in computational terms. For example, the first quantum state approximates the second quantum state when a polynomial time-sampling of the first quantum state gives some desired information or property that it shares with the second quantum state.

Not all quantum computers are gate model quantum computers. Embodiments of the present invention are not limited to being implemented using gate model quantum computers. As an alternative example, embodiments of the present invention may be implemented, in whole or in part, using a quantum computer that is implemented using a quantum annealing architecture, which is an alternative to the gate model quantum computing architecture. More specifically, quantum annealing (QA) is a metaheuristic for finding the global minimum of a given objective function over a given set of candidate solutions (candidate states), by a process using quantum fluctuations.

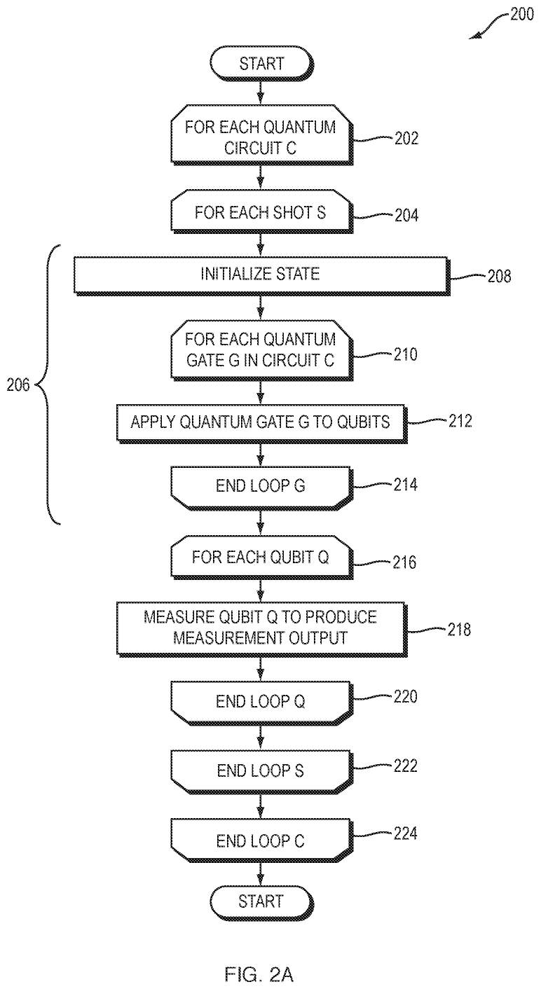

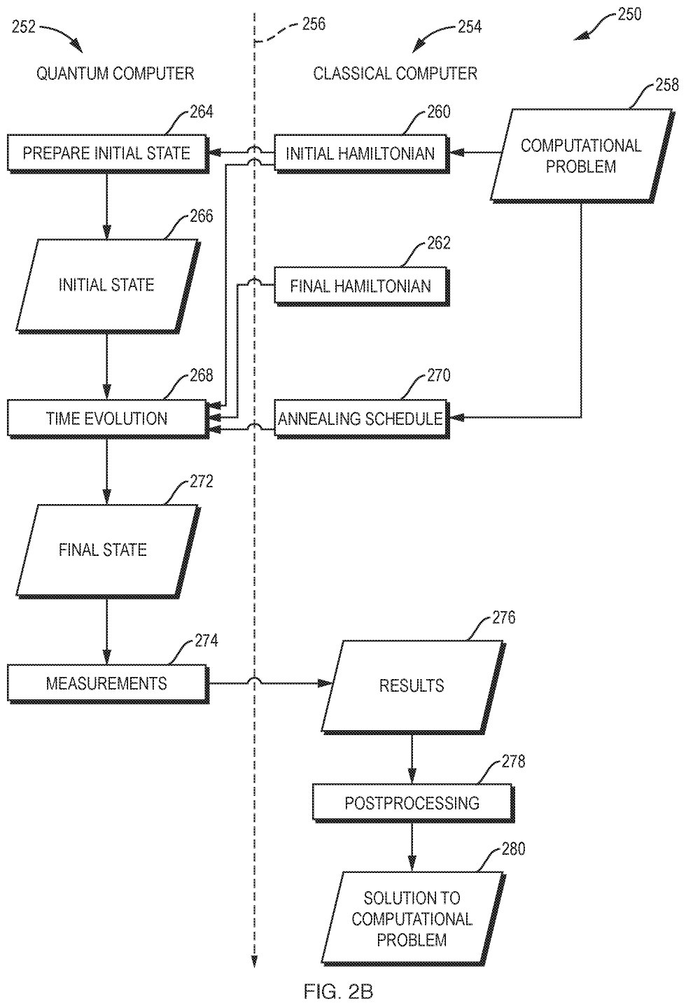

FIG. 2B shows a diagram illustrating operations typically performed by a computer system 250 which implements quantum annealing. The system 250 includes both a quantum computer 252 and a classical computer 254. Operations shown on the left of the dashed vertical line 256 typically are performed by the quantum computer 252, while operations shown on the right of the dashed vertical line 256 typically are performed by the classical computer 254.

Quantum annealing starts with the classical computer 254 generating an initial Hamiltonian 260 and a final Hamiltonian 262 based on a computational problem 258 to be solved, and providing the initial Hamiltonian 260, the final Hamiltonian 262 and an annealing schedule 270 as input to the quantum computer 252. The quantum computer 252 prepares a well-known initial state 266 (FIG. 2B, operation 264), such as a quantum-mechanical superposition of all possible states (candidate states) with equal weights, based on the initial Hamiltonian 260. The classical computer 254 provides the initial Hamiltonian 260, a final Hamiltonian 262, and an annealing schedule 270 to the quantum computer 252. The quantum computer 252 starts in the initial state 266, and evolves its state according to the annealing schedule 270 following the time-dependent Schrödinger equation, a natural quantum-mechanical evolution of physical systems (FIG. 2B, operation 268). More specifically, the state of the quantum computer 252 undergoes time evolution under a time-dependent Hamiltonian, which starts from the initial Hamiltonian 260 and terminates at the final Hamiltonian 262. If the rate of change of the system Hamiltonian is slow enough, the system stays close to the ground state of the instantaneous Hamiltonian. If the rate of change of the system Hamiltonian is accelerated, the system may leave the ground state temporarily but produce a higher likelihood of concluding in the ground state of the final problem Hamiltonian, i.e., diabatic quantum computation. At the end of the time evolution, the set of qubits on the quantum annealer is in a final state 272, which is expected to be close to the ground state of the classical Ising model that corresponds to the solution to the original optimization problem 258. An experimental demonstration of the success of quantum annealing for random magnets was reported immediately after the initial theoretical proposal.

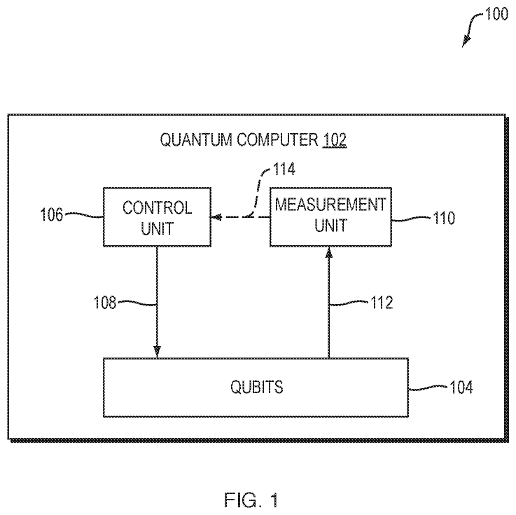

The final state 272 of the quantum computer 254 is measured, thereby producing results 276 (i.e., measurements) (FIG. 2B, operation 274). The measurement operation 274 may be performed, for example, in any of the ways disclosed herein, such as in any of the ways disclosed herein in connection with the measurement unit 110 in FIG. 1. The classical computer 254 performs postprocessing on the measurement results 276 to produce output 280 representing a solution to the original computational problem 258 (FIG. 2B, operation 278).

As yet another alternative example, embodiments of the present invention may be implemented, in whole or in part, using a quantum computer that is implemented using a one-way quantum computing architecture, also referred to as a measurement-based quantum computing architecture, which is another alternative to the gate model quantum computing architecture. More specifically, the one-way or measurement based quantum computer (MBQC) is a method of quantum computing that first prepares an entangled resource state, usually a cluster state or graph state, then performs single qubit measurements on it. It is “one-way” because the resource state is destroyed by the measurements.

The outcome of each individual measurement is random, but they are related in such a way that the computation always succeeds. In general the choices of basis for later measurements need to depend on the results of earlier measurements, and hence the measurements cannot all be performed at the same time.

Any of the functions disclosed herein may be implemented using means for performing those functions. Such means include, but are not limited to, any of the components disclosed herein, such as the computer-related components described below.

Referring to FIG. 1, a diagram is shown of a system 100 implemented according to one embodiment of the present invention. Referring to FIG. 2A, a flowchart is shown of a method 200 performed by the system 100 of FIG. 1 according to one embodiment of the present invention. The system 100 includes a quantum computer 102. The quantum computer 102 includes a plurality of qubits 104, which may be implemented in any of the ways disclosed herein. There may be any number of qubits 104 in the quantum computer 104. For example, the qubits 104 may include or consist of no more than 2 qubits, no more than 4 qubits, no more than 8 qubits, no more than 16 qubits, no more than 32 qubits, no more than 64 qubits, no more than 128 qubits, no more than 256 qubits, no more than 512 qubits, no more than 1024 qubits, no more than 2048 qubits, no more than 4096 qubits, or no more than 8192 qubits. These are merely examples, in practice there may be any number of qubits 104 in the quantum computer 102.

There may be any number of gates in a quantum circuit. However, in some embodiments the number of gates may be at least proportional to the number of qubits 104 in the quantum computer 102. In some embodiments the gate depth may be no greater than the number of qubits 104 in the quantum computer 102, or no greater than some linear multiple of the number of qubits 104 in the quantum computer 102 (e.g., 2, 3, 4, 5, 6, or 7).

The qubits 104 may be interconnected in any graph pattern. For example, they be connected in a linear chain, a two-dimensional grid, an all-to-all connection, any combination thereof, or any subgraph of any of the preceding.

As will become clear from the description below, although element 102 is referred to herein as a “quantum computer,” this does not imply that all components of the quantum computer 102 leverage quantum phenomena. One or more components of the quantum computer 102 may, for example, be classical (i.e., non-quantum components) components which do not leverage quantum phenomena.

The quantum computer 102 includes a control unit 106, which may include any of a variety of circuitry and/or other machinery for performing the functions disclosed herein. The control unit 106 may, for example, consist entirely of classical components. The control unit 106 generates and provides as output one or more control signals 108 to the qubits 104. The control signals 108 may take any of a variety of forms, such as any kind of electromagnetic signals, such as electrical signals, magnetic signals, optical signals (e.g., laser pulses), or any combination thereof.

For example:
In embodiments in which some or all of the qubits 104 are implemented as photons (also referred to as a “quantum optical” implementation) that travel along waveguides, the control unit 106 may be a beam splitter (e.g., a heater or a mirror), the control signals 108 may be signals that control the heater or the rotation of the mirror, the measurement unit 110 may be a photodetector, and the measurement signals 112 may be photons.
In embodiments in which some or all of the qubits 104 are implemented as charge type qubits (e.g., transmon, X-mon, G-mon) or flux-type qubits (e.g., flux qubits, capacitively shunted flux qubits) (also referred to as a “circuit quantum electrodynamic” (circuit QED) implementation), the control unit 106 may be a bus resonator activated by a drive, the control signals 108 may be cavity modes, the measurement unit 110 may be a second resonator (e.g., a low-Q resonator), and the measurement signals 112 may be voltages measured from the second resonator using dispersive readout techniques.
In embodiments in which some or all of the qubits 104 are implemented as superconducting circuits, the control unit 106 may be a circuit QED-assisted control unit or a direct capacitive coupling control unit or an inductive capacitive coupling control unit, the control signals 108 may be cavity modes, the measurement unit 110 may be a second resonator (e.g., a low-Q resonator), and the measurement signals 112 may be voltages measured from the second resonator using dispersive readout techniques.
In embodiments in which some or all of the qubits 104 are implemented as trapped ions (e.g., electronic states of, e.g., magnesium ions), the control unit 106 may be a laser, the control signals 108 may be laser pulses, the measurement unit 110 may be a laser and either a CCD or a photodetector (e.g., a photomultiplier tube), and the measurement signals 112 may be photons.
In embodiments in which some or all of the qubits 104 are implemented using nuclear magnetic resonance (NMR) (in which case the qubits may be molecules, e.g., in liquid or solid form), the control unit 106 may be a radio frequency (RF) antenna, the control signals 108 may be RF fields emitted by the RF antenna, the measurement unit 110 may be another RF antenna, and the measurement signals 112 may be RF fields measured by the second RF antenna.
In embodiments in which some or all of the qubits 104 are implemented as nitrogen-vacancy centers (NV centers), the control unit 106 may, for example, be a laser, a microwave antenna, or a coil, the control signals 108 may be visible light, a microwave signal, or a constant electromagnetic field, the measurement unit 110 may be a photodetector, and the measurement signals 112 may be photons.
In embodiments in which some or all of the qubits 104 are implemented as two-dimensional quasiparticles called “anyons” (also referred to as a “topological quantum computer” implementation), the control unit 106 may be nanowires, the control signals 108 may be local electrical fields or microwave pulses, the measurement unit 110 may be superconducting circuits, and the measurement signals 112 may be voltages.
In embodiments in which some or all of the qubits 104 are implemented as semiconducting material (e.g., nanowires), the control unit 106 may be microfabricated gates, the control signals 108 may be RF or microwave signals, the measurement unit 110 may be microfabricated gates, and the measurement signals 112 may be RF or microwave signals.

Although not shown explicitly in FIG. 1 and not required, the measurement unit 110 may provide one or more feedback signals 114 to the control unit 106 based on the measurement signals 112. For example, quantum computers referred to as “one-way quantum computers” or “measurement-based quantum computers” utilize such feedback 114 from the measurement unit 110 to the control unit 106. Such feedback 114 is also necessary for the operation of fault-tolerant quantum computing and error correction.

The control signals 108 may, for example, include one or more state preparation signals which, when received by the qubits 104, cause some or all of the qubits 104 to change their states. Such state preparation signals constitute a quantum circuit also referred to as an “ansatz circuit.” The resulting state of the qubits 104 is referred to herein as an “initial state” or an “ansatz state.” The process of outputting the state preparation signal(s) to cause the qubits 104 to be in their initial state is referred to herein as “state preparation” (FIG. 2A, section 206). A special case of state preparation is “initialization,” also referred to as a “reset operation,” in which the initial state is one in which some or all of the qubits 104 are in the “zero” state i.e. the default single-qubit state. More generally, state preparation may involve using the state preparation signals to cause some or all of the qubits 104 to be in any distribution of desired states. In some embodiments, the control unit 106 may first perform initialization on the qubits 104 and then perform preparation on the qubits 104, by first outputting a first set of state preparation signals to initialize the qubits 104, and by then outputting a second set of state preparation signals to put the qubits 104 partially or entirely into non-zero states.

Another example of control signals 108 that may be output by the control unit 106 and received by the qubits 104 are gate control signals. The control unit 106 may output such gate control signals, thereby applying one or more gates to the qubits 104. Applying a gate to one or more qubits causes the set of qubits to undergo a physical state change which embodies a corresponding logical gate operation (e.g., single-qubit rotation, two-qubit entangling gate or multi-qubit operation) specified by the received gate control signal. As this implies, in response to receiving the gate control signals, the qubits 104 undergo physical transformations which cause the qubits 104 to change state in such a way that the states of the qubits 104, when measured (see below), represent the results of performing logical gate operations specified by the gate control signals. The term “quantum gate,” as used herein, refers to the application of a gate control signal to one or more qubits to cause those qubits to undergo the physical transformations described above and thereby to implement a logical gate operation.

It should be understood that the dividing line between state preparation (and the corresponding state preparation signals) and the application of gates (and the corresponding gate control signals) may be chosen arbitrarily. For example, some or all the components and operations that are illustrated in FIGS. 1 and 2A-2B as elements of “state preparation” may instead be characterized as elements of gate application. Conversely, for example, some or all of the components and operations that are illustrated in FIGS. 1 and 2A-2B as elements of “gate application” may instead be characterized as elements of state preparation. As one particular example, the system and method of FIGS. 1 and 2A-2B may be characterized as solely performing state preparation followed by measurement, without any gate application, where the elements that are described herein as being part of gate application are instead considered to be part of state preparation. Conversely, for example, the system and method of FIGS. 1 and 2A-2B may be characterized as solely performing gate application followed by measurement, without any state preparation, and where the elements that are described herein as being part of state preparation are instead considered to be part of gate application.

The quantum computer 102 also includes a measurement unit 110, which performs one or more measurement operations on the qubits 104 to read out measurement signals 112 (also referred to herein as “measurement results”) from the qubits 104, where the measurement results 112 are signals representing the states of some or all of the qubits 104. In practice, the control unit 106 and the measurement unit 110 may be entirely distinct from each other, or contain some components in common with each other, or be implemented using a single unit (i.e., a single unit may implement both the control unit 106 and the measurement unit 110). For example, a laser unit may be used both to generate the control signals 108 and to provide stimulus (e.g., one or more laser beams) to the qubits 104 to cause the measurement signals 112 to be generated.

In general, the quantum computer 102 may perform various operations described above any number of times. For example, the control unit 106 may generate one or more control signals 108, thereby causing the qubits 104 to perform one or more quantum gate operations. The measurement unit 110 may then perform one or more measurement operations on the qubits 104 to read out a set of one or more measurement signals 112. The measurement unit 110 may repeat such measurement operations on the qubits 104 before the control unit 106 generates additional control signals 108, thereby causing the measurement unit 110 to read out additional measurement signals 112 resulting from the same gate operations that were performed before reading out the previous measurement signals 112. The measurement unit 110 may repeat this process any number of times to generate any number of measurement signals 112 corresponding to the same gate operations. The quantum computer 102 may then aggregate such multiple measurements of the same gate operations in any of a variety of ways.

After the measurement unit 110 has performed one or more measurement operations on the qubits 104 after they have performed one set of gate operations, the control unit 106 may generate one or more additional control signals 108, which may differ from the previous control signals 108, thereby causing the qubits 104 to perform one or more additional quantum gate operations, which may differ from the previous set of quantum gate operations. The process described above may then be repeated, with the measurement unit 110 performing one or more measurement operations on the qubits 104 in their new states (resulting from the most recently-performed gate operations).

In general, the system 100 may implement a plurality of quantum circuits as follows. For each quantum circuit C in the plurality of quantum circuits (FIG. 2A, operation 202), the system 100 performs a plurality of “shots” on the qubits 104. The meaning of a shot will become clear from the description that follows. For each shot S in the plurality of shots (FIG. 2A, operation 204), the system 100 prepares the state of the qubits 104 (FIG. 2A, section 206). More specifically, for each quantum gate G in quantum circuit C (FIG. 2A, operation 210), the system 100 applies quantum gate G to the qubits 104 (FIG. 2A, operations 212 and 214).

Then, for each of the qubits Q 104 (FIG. 2A, operation 216), the system 100 measures the qubit Q to produce measurement output representing a current state of qubit Q (FIG. 2A, operations 218 and 220).

The operations described above are repeated for each shot S (FIG. 2A, operation 222), and circuit C (FIG. 2A, operation 224). As the description above implies, a single “shot” involves preparing the state of the qubits 104 and applying all of the quantum gates in a circuit to the qubits 104 and then measuring the states of the qubits 104; and the system 100 may perform multiple shots for one or more circuits.

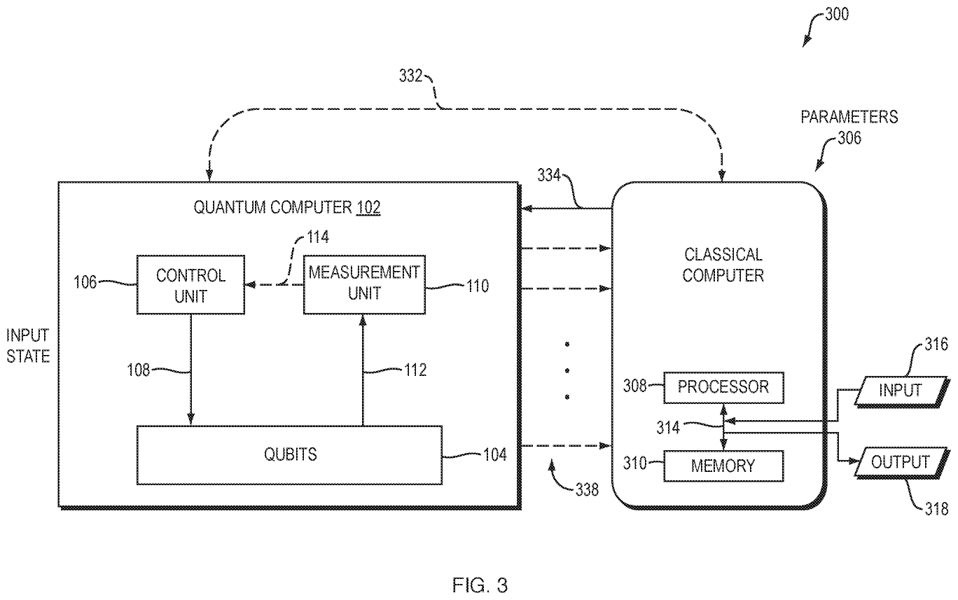

Referring to FIG. 3, a diagram is shown of a hybrid classical quantum computer (HQC) 300 implemented according to one embodiment of the present invention. The HQC 300 includes a quantum computer component 102 (which may, for example, be implemented in the manner shown and described in connection with FIG. 1) and a classical computer component 306. The classical computer component may be a machine implemented according to the general computing model established by John Von Neumann, in which programs are written in the form of ordered lists of instructions and stored within a classical (e.g., digital) memory 310 and executed by a classical (e.g., digital) processor 308 of the classical computer. The memory 310 is classical in the sense that it stores data in a storage medium in the form of bits, which have a single definite binary state at any point in time. The bits stored in the memory 310 may, for example, represent a computer program. The classical computer component 304 typically includes a bus 314. The processor 308 may read bits from and write bits to the memory 310 over the bus 314. For example, the processor 308 may read instructions from the computer program in the memory 310, and may optionally receive input data 316 from a source external to the computer 302, such as from a user input device such as a mouse, keyboard, or any other input device. The processor 308 may use instructions that have been read from the memory 310 to perform computations on data read from the memory 310 and/or the input 316, and generate output from those instructions. The processor 308 may store that output back into the memory 310 and/or provide the output externally as output data 318 via an output device, such as a monitor, speaker, or network device.

The quantum computer component 102 may include a plurality of qubits 104, as described above in connection with FIG. 1. A single qubit may represent a one, a zero, or any quantum superposition of those two qubit states. The classical computer component 304 may provide classical state preparation signals Y32 to the quantum computer 102, in response to which the quantum computer 102 may prepare the states of the qubits 104 in any of the ways disclosed herein, such as in any of the ways disclosed in connection with FIGS. 1 and 2A-2B.

Once the qubits 104 have been prepared, the classical processor 308 may provide classical control signals Y34 to the quantum computer 102, in response to which the quantum computer 102 may apply the gate operations specified by the control signals Y32 to the qubits 104, as a result of which the qubits 104 arrive at a final state. The measurement unit 110 in the quantum computer 102 (which may be implemented as described above in connection with FIGS. 1 and 2A-2B) may measure the states of the qubits 104 and produce measurement output Y38 representing the collapse of the states of the qubits 104 into one of their eigenstates. As a result, the measurement output Y38 includes or consists of bits and therefore represents a classical state. The quantum computer 102 provides the measurement output Y38 to the classical processor 308. The classical processor 308 may store data representing the measurement output Y38 and/or data derived therefrom in the classical memory 310.

The steps described above may be repeated any number of times, with what is described above as the final state of the qubits 104 serving as the initial state of the next iteration. In this way, the classical computer 304 and the quantum computer 102 may cooperate as co-processors to perform joint computations as a single computer system.

In one embodiment, the invention implements an improvement to the variational quantum eigensolver (VQE), in which the number of shots to be performed in order to apply the VQE method is reduced by applying a quantum circuit corresponding to an orbital rotation of the quantum state during each shot instead of applying single-qubit context-selection gates or, more generally, context-selection gates from any Pauli-based grouping method. A shot in the invention comprises qubit initialization, application of the ansatz circuit, application of an orbital rotation, and measurement.

The starting point for the VQE approach is an operator which describes the quantum mechanical behavior of electrons—the Hamiltonian. The Hamiltonian may be expressed as the sum of one- and two-body component operators as follows:

$$H = {\sum }_{p , q = 1}^{N} {h}_{pq} {a}_{p}^{†} {a}_{q} + {\sum }_{p , q , r , s = 1}^{N} {h}_{pqrs} {a}_{p}^{†} {a}_{q}^{†} {a}_{r} {a}_{s} \qquad ( 1 )$$

where
N is the number of spin orbitals in the basis set,
p, q, r, and s are indices corresponding to the spin orbitals,
aₚ^{†} and aₚ are the creation and annihilation operators corresponding to spin-orbital ϕₚ,
h_{pq} are the one-body coefficients that describe the kinetic energy and external potential operators,
h_{pqrs} are the two-body coefficients corresponding to the interaction between electrons,

As discussed by Motta et al., Hamiltonians of this form can be decomposed, e.g. via a low-rank decomposition method such as Cholesky decomposition or eigendecomposition of the two-body supermatrix and subsequent diagonalization of the auxiliary matrices. One can additionally diagonalize the resulting matrix of one-body coefficients to obtain a representation of the Hamiltonian of the form

H=Σᵢ₌₁^{N}λᵢ⁽⁰⁾nᵢ⁽⁰⁾+ [symbol] Σ_{i,j=1}^{N} [symbol] [symbol] (2)

where

[symbol]

= [symbol] (3)

and where
[symbol] and [symbol] are the creation and annihilation operators corresponding to the single-particle orbital

$${ψ}_{i}^{( 𝓁 )} = {\sum }_{j} {U}_{ji}^{( 𝓁 )} {φ}_{j}$$

where [symbol] is an N×N matrix obtained from the decomposition,
[symbol] is the index of single-particle orbital bases { [symbol] } (where i runs from 1 to N) obtained by the decomposition, and by which each value of [symbol] indexes a different, so-called, orbital frame,
p, q, i, and j are indices of spin-orbitals within a given basis,
h′ is an N×N matrix obtained from the decomposition and represents the coefficients of the one-body operators as well as a correction arising from the re-ordering of operators in the two-body terms, and
[symbol] is a real or complex number obtained from the decomposition,

The annihilation operators of the new and old bases are related through a unitary transformation:

[symbol]

= [symbol] (4)

where

$${κ}^{( 𝓁 )} = {\sum }_{p , q = 1}^{N} {V}_{pq}^{( 𝓁 )} {a}_{p}^{†} {a}_{q} \qquad ( 5 )$$

and [symbol] is the matrix logarithm of [symbol] . The matrix [symbol] is referred to as an orbital rotation.

The decomposition in Eq. (2) provides an efficient method for evaluating [symbol] Ψ|H|Ψ [symbol] , where |Ψ [symbol] is a trial wavefunction. Combining Eq. (3) and (4), along with the unitarity of the orbital rotation operator [symbol] , shows that

[symbol]

Ψ| [symbol] |Ψ [symbol] = [symbol] Ψ| [symbol] nᵢnⱼ [symbol] |Ψ [symbol] (6)

Consequently, the expectation value of each term in the double sum of Eq. (2) can be computed as the expectation value of nᵢnⱼ with respect to the state [symbol] |Ψ [symbol] . This state can readily be prepared by, for example, preparing the state |Ψ [symbol] and then using a Givens decomposition to implement the orbital rotation operator as one- and two-qubit gates.

Because the operators {nᵢnⱼ} commute for all i and j, the above strategy allows one, for a given [symbol] , to measure all [symbol] Ψ| [symbol] |Ψ [symbol] simultaneously. For example, in the case of the Jordan-Wigner encoding, the operator nᵢnⱼ maps to ZᵢZⱼ, and so one would prepare the state [symbol] |Ψ [symbol] and measure each qubit in the Z basis. For each given [symbol] , this process would be repeated until the expectation values [symbol] Ψ| [symbol] |Ψ [symbol] had been determined to a sufficient accuracy.

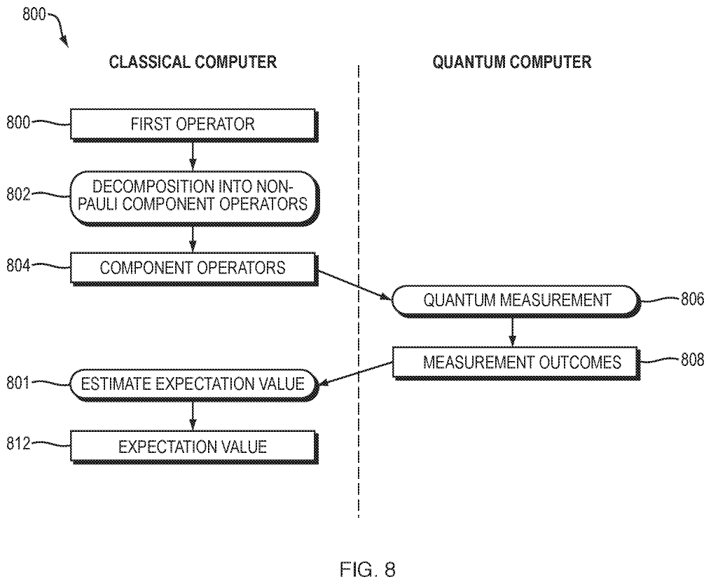

Referring to FIG. 8, a flowchart is shown of a method 800 performed by a classical computer or a hybrid quantum-classical (HQC) computer according to one embodiment of the present invention. In general, the method 800 may be used with any operator 801, which may be decomposed 802 into a plurality of component operators 804 whose expectation values are measurable on a quantum computer. A measurement module may then be applied by measuring 806, on a quantum computer, at least one of the component operators to produce measurement outcomes 808, and on a classical computer, computing 810 the expectation value 812 of the operator by averaging the measurement outcomes 808. While Pauli-based grouping constitutes all of the component operators being products of Pauli operators, embodiments of the present invention utilize non-Pauli operators to improve measurement efficiency.

In a more general setting, some embodiments utilize a decomposition 802 into component operators that are different from those of Eq. (1). In one embodiment, the decomposition comprises component operators forming a linear combination of orbital-rotated diagonal operators. In other embodiments, the operator decomposes into two parts. In one part, the component operators comprise a linear combination of orbital-rotated diagonal operators, while a second part of the decomposition utilizes a method other than a linear combination of orbital-rotated diagonal operators. In one embodiment, the orbital rotations may be chosen so as to minimize the quantum circuit depth of the measurement module, thereby reducing noise in the quantum computer.

In one embodiment, all component operator expectation value estimates are used to estimate the expectation value of the operator. In another embodiment, only a proper subset of component operator expectation value estimates are used to estimate the expectation value of the operator. This is because some component operators may contribute little to the overall expectation value. In another embodiment, weighted averaging of the component operators may be performed to minimize the overall variance, since as the variance of individual expectation values may differ.

The expectation value of the terms nᵢ⁽⁰⁾ can be measured in a similar fashion using the relation

[symbol]

Ψ|nᵢ⁽⁰⁾|Ψ [symbol] = [symbol] Ψ|e^{K}^{⁽⁰⁾}nᵢe^{-K}^{⁽⁰⁾}|Ψ [symbol] (7)

This relation shows that the expectation value [symbol] Ψ|nᵢ⁽⁰⁾|Ψ [symbol] can be computed as the expectation value of nᵢ with respect to e^{-K}^{⁽⁰⁾}|Ψ [symbol] . Because the operators {nᵢ} commute for all i, this strategy allows one to measure all [symbol] Ψ|nᵢ⁽⁰⁾|Ψ [symbol] simultaneously. in the case of the Jordan-Wigner encoding, the operator nᵢ maps to Zᵢ, and so one would prepare the state e^{-K}^{⁽⁰⁾}|Ψ [symbol] and measure each qubit in the Z basis. This process would be repeated until the expectation values [symbol] Ψ|nᵢ⁽⁰⁾|Ψ [symbol] had been determined to a sufficient accuracy.

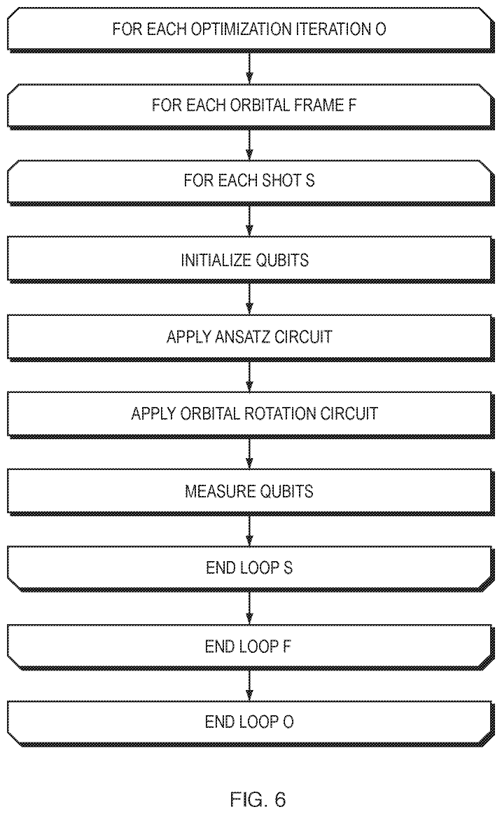

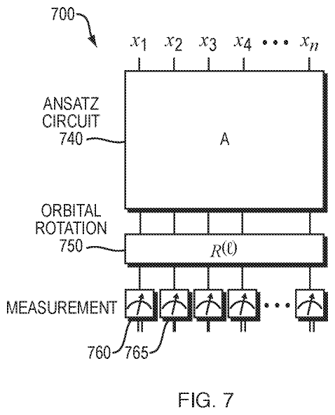

FIG. 6 shows a flowchart that illustrates a method performed by one embodiment of the present invention, in which the system 600 may be used to perform the orbital-frames decomposition of the electronic structure Hamiltonian or another operator of interest. For each step in the optimization of the ansatz parameters, a plurality of orbital frames are considered. For each orbital frame, a plurality of shots are performed on a quantum computer. Each shot consists of the execution of a quantum circuit schematically shown in FIG. 7. The circuit 700 includes the initialization of the qubits, the application of the ansatz circuit 740 to prepare a state corresponding to the trial wavefunction, the application of a circuit corresponding to an orbital rotation [symbol] 750 where [symbol] is the index of the current frame in Loop F, and the measurement of qubits 760 (which corresponds to the measurement unit 110 in FIG. 1).

The measurement results obtained in each iteration of Loop F are used to evaluate the expectation value of nᵢ⁽⁰⁾ for all i and the expectation value of [symbol] for all i and j for [symbol] >0. For each iteration of Loop O, the expectation values of nᵢ⁽⁰⁾ for all i and expectation values of [symbol] for all i, j, for [symbol] >0 are used to calculate the expectation value of the Hamiltonian or other operator of interest. In some embodiments, Loop F is repeated over all orbital frames obtained from the decomposition. The number of repetitions for Loops O and S are at the discretion of the user and will typically depend on the desired accuracy of the calculation, with a greater number of iterations corresponding to a more accurate calculation. The number of repetitions of Loop S may differ for each iteration of Loops O and F, and methods presented in the literature for determining the accuracy of an estimate of the sum of expectation values may be employed to guide the number of repetitions of Loop S.

In some embodiments, the objective function being minimized in Eq. 7 above is the expectation value of the Hamiltonian. In other embodiments the objective function is the expectation value of an operator that is equal to the Hamiltonian plus penalty terms that constrain the wavefunction to a subspace of interest. This may include penalties to constrain the number of particles, the spin state of the electronic wavefunction, or ensure orthogonality to other energy eigenstates so as to allow for the calculation of the energy of excited states.

The variationally minimized expectation value of the Hamiltonian or other operator of interest may then be used to determine the extent of the attribute of the system.

In some embodiments, Eq. 5 may be restricted to only a subset of the values of [symbol] in order to further reduce the number of shots required. Many decomposition techniques will result in many values of [symbol] having a negligible contribution to the total energy, and so such values can be excluded with only minimal loss of accuracy. In such embodiments, the expectation value of the Hamiltonian is approximated as

[symbol]

Ψ|H|Ψ [symbol] ≈ [symbol] Ψ|Σ_{p,q=1}^{N}h′_{pq}aₚ^{†}a_{q}+ [symbol] ₌₁Σ_{i,k=1}^{N} [symbol] [symbol] |Ψ [symbol] (8)

where L is the number of orbital frames to be included in the approximation and is less than or equal to N². (Without loss of generality, this notation assumes that the frames are ordered such that those to be included have lower indices [symbol] than those to be excluded.) In some embodiments, L may grow linearly as a function of N.

In some embodiments, the expectation values of some orbital frames with respect to the trial state |Ψ> may be approximated by their expectation value with respect to an approximation to |Ψ> and evaluated using a classical computer, thereby reducing the number of shots needed to be performed on the quantum computer. In this embodiment, the expectation value of the Hamiltonian is approximated as

[symbol]

Ψ|H|Ψ [symbol] ≈ [symbol] Ψ|Σᵢ₌₁^{N}λᵢ⁽⁰⁾nᵢ⁽⁰⁾+ [symbol] Σ_{i,j=1}^{N} [symbol] [symbol] |Ψ [symbol] + [symbol] Ψ₀| [symbol] Σ_{i,j=1}^{N} [symbol] [symbol] |Ψ₀ [symbol] (9)

where |Ψ₀> is an approximation to the trial wavefunction |Ψ> and L is the number of orbital frames whose expectation value is not to be approximated and is less than or equal to N². (Without loss of generality, this notation assumes that the frames are ordered such that those not to be approximated have lower indices [symbol] than those to be approximated.) In some embodiments, L may be approximately equal to N. In the above equation, the first expectation value on the right-hand side is evaluated using a hybrid quantum/classical computer and the second using a classical computer. In some embodiments, the wavefunction |Ψ₀> is a Hartree-Fock wavefunction. In other embodiments, the second expectation value on the right-hand side is approximated using M∅ller-Plesset perturbation theory.

While some embodiments use an orbital frames decomposition to reduce the number of shots required to compute the ground state energy of a molecule or extended system, other embodiments use the orbital frames decomposition to reduce the number of shots required for computing the energies of excited states of molecules or extended systems.

In some embodiments, a more general decomposition of the Hamiltonian is used instead of Eq. (2)

$$H = {\sum }_{𝓁 = 1}^{L} [ {\sum }_{{i}_{1}}^{N} {g}_{{i}_{1}}^{( 𝓁 , 1 )} {n}_{{i}_{1}}^{( 𝓁 )} + {\sum }_{{i}_{1} , {i}_{2} = 1}^{N} {g}_{{i}_{1} {i}_{2}}^{( 𝓁 , 2 )} {n}_{{i}_{1}}^{( 𝓁 )} {n}_{{i}_{2}}^{( 𝓁 )} + {\sum }_{{i}_{1} , {i}_{2} , {i}_{3} = 1}^{N} {g}_{{i}_{1} {i}_{2} {i}_{3}}^{( 𝓁 , 3 )} {n}_{{i}_{1}}^{( 𝓁 )} {n}_{{i}_{2}}^{( 𝓁 )} {n}_{{i}_{3}}^{( 𝓁 )} + • {\sum }_{{i}_{1} , {i}_{2} , • {i}_{K} = 1}^{N} {g}_{{i}_{1} , {i}_{2} • {i}_{K}}^{( 𝓁 , 3 )} {n}_{{i}_{1}}^{( 𝓁 )} {n}_{{i}_{2}}^{( 𝓁 )} • {n}_{K}^{( 𝓁 )} ] \qquad ( 10 )$$

where
[symbol] represent coefficients for the k-body terms obtained from a decomposition of the Hamiltonian,
L is the number of frames in the decomposition,
K is the highest order term appearing in the

Hamiltonian and is equal to 2 when the Hamiltonian is the electronic structure Hamiltonian (Eq. (1),
i and j index the spin orbitals, and
[symbol] and n are the same as in Eq. (2).
   While the decomposition in Eq. (2) only can be applied to two-body Hamiltonians (such as the electronic structure Hamiltonian), the decomposition in Eq. (10) can be applied to a Hamiltonians that include three-body or higher interactions. The coefficients [symbol] , number of frames L, and corresponding orbital rotations [symbol] are chosen to reduce the total number of measurements required in order to estimate the expectation value of the Hamiltonian with respect to a trial wavefunction. In some embodiments, these values are chosen so as to reduce the depth of the circuit associated with implementing the orbital rotation represented by [symbol] on a quantum computer. In some embodiments, the expectation values of some of the frames of the Hamiltonian decomposition of Eq. (10) are approximated using classical techniques, analogous to the approach described for Eq. (9).

In some embodiments, the Hamiltonian is split into two components and the orbital frames approach is applied to one component and a second measurement strategy is applied to the other component. In some embodiments, this second measurement strategy is the conventional VQE approach based on the grouping of co-measurable terms, as depicted in FIG. 1. In some embodiments, the second component is comprised of all terms in the Hamiltonian that are number operators or products of number operators and are therefore co-measureable when the Jordan-Wigner transformation is used.

The disclosed improvements to the VQE process result in a slightly longer circuit than the conventional approach but require a significantly smaller number of shots to obtain the desired results. Consequently the amount of time needed to perform VQE can be significantly reduced.

One embodiment of the present invention is directed to a method for using a measurement module to compute an expectation value of a first operator more efficiently than Pauli-based grouping, where the first operator comprises a plurality of component operators, and where at least one of the plurality of component operators is not a product of Pauli operators. The method may include: (1) computing the expectation value of the first operator. Computing the expectation value of the first operator may include: (a) on a quantum computer, using the measurement module to make a quantum measurement of at least one of the plurality of component operators, to produce a plurality of measurement outcomes of the at least one of the plurality of component operators; and (b) on a classical computer, computing the expectation value of the first operator by averaging at least some of the plurality of measurement outcomes.

The method may further include, before (1), decomposing the first operator into a decomposition of the plurality of component operators. Decomposing the first operator into the plurality of component operators may include decomposing the first operator into a linear combination of orbital-rotated diagonal operators. Decomposing the first operator into the linear combination of orbital-rotated diagonal operators may include choosing orbital rotations of the decomposition so as to minimize a depth of the measurement module. The first operator may include a two-body fermionic Hamiltonian, and decomposing the first operator into the plurality of component operators may include decomposing the first operator into the plurality of component operators using a low-rank decomposition method. Decomposing the first operator may include decomposing a first part of the first operator using a linear combination of orbital-rotated diagonal operators and decomposing a second part of the first operator using a method other than a linear combination of orbital-rotated diagonal operators.

Making the quantum measurement may include, for each component operator, applying a corresponding orbital rotation. The method may further include, on the classical computer, computing a plurality of component operator expectation values based on the plurality of measurement outcomes. Computing the expectation value of the operator may include averaging all of the plurality of component operator expectation values. Computing the expectation value of the operator may include averaging a proper subset of the plurality of component operator expectation values. Averaging the at least some of the plurality of measurement outcomes may include computing a weighted average of the at least some of the plurality of measurement outcomes.

The first operator may be a Hamiltonian operator. The first operator may be a sum of a Hamiltonian operator and a penalty operator. The penalty operator may enforce particle number symmetry. The penalty operator may enforce spin symmetry. The penalty operator may enforce orthogonality with respect to another state.

The method may further include estimating excited state energies of the first operator.

Another embodiment of the present invention is directed to a system for using a measurement module to compute an expectation value of a first operator more efficiently than Pauli-based grouping. The first operator may include a plurality of component operators. At least one of the plurality of component operators may not be a product of Pauli operators. The system may include: a quantum computer comprising the measurement module, wherein the measurement module is adapted to make a quantum measurement of at least one of the plurality of component operators, to produce a plurality of measurement outcomes of the at least one of the plurality of component operators; and a classical computer comprising at least one processor and at least one non-transitory computer-readable medium comprising computer program instructions which, when executed by the at least one processor, cause the at least one processor to compute the expectation value of the operator by averaging at least some of the plurality of measurement outcomes.

The computer program instructions may further include computer program instructions which, when executed by the at least one processor, cause the at least one processor to decompose the first operator into a decomposition of the plurality of component operators. Decomposing the first operator into the plurality of component operators may include decomposing the first operator into a linear combination of orbital-rotated diagonal operators. Decomposing the first operator into the linear combination of orbital-rotated diagonal operators comprises choosing orbital rotations of the decomposition so as to minimize a depth of the measurement module. The first operator may be a two-body fermionic Hamiltonian, and decomposing the first operator into the plurality of component operators may include decomposing the first operator into the plurality of component operators using a low-rank decomposition method. Decomposing the first operator may include decomposing a first part of the first operator using a linear combination of orbital-rotated diagonal operators and decomposing a second part of the first operator using a method other than a linear combination of orbital-rotated diagonal operators.

The measurement module may further include means for applying a corresponding orbital rotation for each component operator.

The computer program instructions may further include computer program instructions which, when executed by the at least one processor, cause the at least one processor to compute a plurality of component operator expectation values based on the plurality of measurement outcomes. Computing the expectation value of the operator may include averaging all of the plurality of component operator expectation values. Computing the expectation value of the operator may include averaging a proper subset of the plurality of component operator expectation values. Averaging the at least some of the plurality of measurement outcomes may include computing a weighted average of the at least some of the plurality of measurement outcomes.

The first operator may be a Hamiltonian operator. The first operator may be a sum of a Hamiltonian operator and a penalty operator. The penalty operator may enforce particle number symmetry. The penalty operator may enforce spin symmetry. The penalty operator may enforce orthogonality with respect to another state.

The computer program instructions may further include computer program instructions which, when executed by the at least one computer processor, cause the at least one computer processor to estimate excited state energies of the first operator.

Any of the methods and systems herein may be implemented, in whole or in part, by a classical computer which simulates functions disclosed herein as being performed by a quantum computer. For example, one embodiment of the present invention is directed to a method for computing an expectation value of a first operator more efficiently than Pauli-based grouping, the first operator comprising a plurality of component operators, wherein at least one of the plurality of component operators is not a product of Pauli operators, the method performed by a classical computer comprising at least one processor and at least one non-transitory computer-readable medium comprising computer program instructions executable by the at least one processor to perform the method. The method includes: 1) computing the expectation value of the first operator. Computing the expectation value of the first operator includes: (a) simulating a quantum computer measurement module to make a simulated quantum measurement of at least one of the plurality of component operators, to produce a plurality of measurement outcomes of the at least one of the plurality of component operators; and (b) computing the expectation value of the first operator by averaging at least some of the plurality of measurement outcomes. The method may perform (b) using a Hartree Fock state and/or Moller-Plesset perturbation theory.

Another embodiment of the present invention is directed to a system for computing an expectation value of a first operator more efficiently than Pauli-based grouping, the first operator comprising a plurality of component operators, wherein at least one of the plurality of component operators is not a product of Pauli operators, the system comprising at least one non-transitory computer-readable medium comprising computer program instructions executable by at least one processor to perform a method. The method includes: 1) computing the expectation value of the first operator. Computing the expectation value of the first operator includes: (a) simulating a quantum computer measurement module to make a simulated quantum measurement of at least one of the plurality of component operators, to produce a plurality of measurement outcomes of the at least one of the plurality of component operators; and (b) computing the expectation value of the first operator by averaging at least some of the plurality of measurement outcomes. The method may perform (b) using a Hartree Fock state and/or Moller-Plesset perturbation theory.

The techniques described above may be implemented, for example, in hardware, in one or more computer programs tangibly stored on one or more computer-readable media, firmware, or any combination thereof, such as solely on a quantum computer, solely on a classical computer, or on a hybrid classical quantum (HQC) computer. The techniques disclosed herein may, for example, be implemented solely on a classical computer, in which the classical computer emulates the quantum computer functions disclosed herein.

The techniques described above may be implemented in one or more computer programs executing on (or executable by) a programmable computer (such as a classical computer, a quantum computer, or an HQC) including any combination of any number of the following: a processor, a storage medium readable and/or writable by the processor (including, for example, volatile and non-volatile memory and/or storage elements), an input device, and an output device. Program code may be applied to input entered using the input device to perform the functions described and to generate output using the output device.

Embodiments of the present invention include features which are only possible and/or feasible to implement with the use of one or more computers, computer processors, and/or other elements of a computer system. Such features are either impossible or impractical to implement mentally and/or manually. For example, embodiments of the present invention implement the variational quantum eigensolver (VQE), which is a quantum algorithm which is implemented on a quantum computer. Such an algorithm cannot be performed mentally or manually and therefore is inherently rooted in computer technology generally and in quantum computer technology specifically.

Any claims herein which affirmatively require a computer, a processor, a memory, or similar computer-related elements, are intended to require such elements, and should not be interpreted as if such elements are not present in or required by such claims. Such claims are not intended, and should not be interpreted, to cover methods and/or systems which lack the recited computer-related elements. For example, any method claim herein which recites that the claimed method is performed by a computer, a processor, a memory, and/or similar computer-related element, is intended to, and should only be interpreted to, encompass methods which are performed by the recited computer-related element(s). Such a method claim should not be interpreted, for example, to encompass a method that is performed mentally or by hand (e.g., using pencil and paper). Similarly, any product claim herein which recites that the claimed product includes a computer, a processor, a memory, and/or similar computer-related element, is intended to, and should only be interpreted to, encompass products which include the recited computer-related element(s). Such a product claim should not be interpreted, for example, to encompass a product that does not include the recited computer-related element(s).Each computer program within the scope of the claims below may be implemented in any programming language, such as assembly language, machine language, a high-level procedural programming language, or an object-oriented programming language. The programming language may, for example, be a compiled or interpreted programming language. Each such computer program may be implemented in a computer program product tangibly embodied in a machine-readable storage device for execution by a computer processor. Method steps of the invention may be performed by one or more computer processors executing a program tangibly embodied on a computer-readable medium to perform functions of the invention by operating on input and generating output. Suitable processors include, by way of example, both general and special purpose microprocessors. Generally, the processor receives (reads) instructions and data from a memory (such as a read-only memory and/or a random access memory) and writes (stores) instructions and data to the memory. Storage devices suitable for tangibly embodying computer program instructions and data include, for example, all forms of non-volatile memory, such as semiconductor memory devices, including EPROM, EEPROM, and flash memory devices; magnetic disks such as internal hard disks and removable disks; magneto-optical disks; and CD-ROMs. Any of the foregoing may be supplemented by, or incorporated in, specially-designed ASICs (application-specific integrated circuits) or FPGAs (Field-Programmable Gate Arrays). A computer can generally also receive (read) programs and data from, and write (store) programs and data to, a non-transitory computer-readable storage medium such as an internal disk (not shown) or a removable disk. These elements will also be found in a conventional desktop or workstation computer as well as other computers suitable for executing computer programs implementing the methods described herein, which may be used in conjunction with any digital print engine or marking engine, display monitor, or other raster output device capable of producing color or gray scale pixels on paper, film, display screen, or other output medium.

Any data disclosed herein may be implemented, for example, in one or more data structures tangibly stored on a non-transitory computer-readable medium (such as a classical computer-readable medium, a quantum computer-readable medium, or an HQC computer-readable medium). Embodiments of the invention may store such data in such data structure(s) and read such data from such data structure(s).

What is claimed is:

1. A method for using a measurement module to compute an expectation value of a first operator more efficiently than Pauli-based grouping, the first operator comprising a plurality of component operators, wherein at least one of the plurality of component operators is not a product of Pauli operators, the method comprising:
1) computing the expectation value of the first operator, comprising:
(a) on a quantum computer, using the measurement module to make a quantum measurement of at least one of the plurality of component operators, to produce a plurality of measurement outcomes of the at least one of the plurality of component operators; and
(b) on a classical computer, computing the expectation value of the first operator by averaging at least some of the plurality of measurement outcomes.

2. The method of claim 1, further comprising, before (1), decomposing the first operator into a decomposition of the plurality of component operators.

3. The method of claim 2, whereby decomposing the first operator into the plurality of component operators comprises decomposing the first operator into a linear combination of orbital-rotated diagonal operators.

4. The method of claim 2, wherein decomposing the first operator into the linear combination of orbital-rotated diagonal operators comprises choosing orbital rotations of the decomposition so as to minimize a depth of the measurement module.

5. The method of claim 2, wherein the first operator comprises a two-body fermionic Hamiltonian, and wherein decomposing the first operator into the plurality of component operators comprises decomposing the first operator into the plurality of component operators using a low-rank decomposition method.

6. The method of claim 2, wherein decomposing the first operator comprises decomposing a first part of the first operator using a linear combination of orbital-rotated diagonal operators and decomposing a second part of the first operator using a method other than a linear combination of orbital-rotated diagonal operators.

7. The method of claim 1, wherein making the quantum measurement comprises, for each component operator, applying a corresponding orbital rotation.

8. The method of claim 1, further comprising, on the classical computer, computing a plurality of component operator expectation values based on the plurality of measurement outcomes.

9. The method of claim 8, wherein computing the expectation value of the operator comprises averaging all of the plurality of component operator expectation values.

10. The method of claim 8, wherein computing the expectation value of the operator comprises averaging a proper subset of the plurality of component operator expectation values.

11. The method of claim 1, wherein averaging the at least some of the plurality of measurement outcomes comprises computing a weighted average of the at least some of the plurality of measurement outcomes.

12. The method of claim 1, wherein the first operator comprises a Hamiltonian operator.

13. The method of claim 1, wherein the first operator comprises a sum of a Hamiltonian operator and a penalty operator.

14. The method of claim 13, wherein the penalty operator enforces particle number symmetry.

15. The method of claim 13, wherein the penalty operator enforces spin symmetry.

16. The method of claim 13, wherein the penalty operator enforces orthogonality with respect to another state.

17. The method of claim 1, further comprising estimating excited state energies of the first operator.

18. A system for using a measurement module to compute an expectation value of a first operator more efficiently than Pauli-based grouping, the first operator comprising a plurality of component operators, wherein at least one of the plurality of component operators is not a product of Pauli operators, the system comprising:
a quantum computer comprising the measurement module, wherein the measurement module is adapted to make a quantum measurement of at least one of the plurality of component operators, to produce a plurality of measurement outcomes of the at least one of the plurality of component operators; and
a classical computer comprising at least one processor and at least one non-transitory computer-readable medium comprising computer program instructions which, when executed by the at least one processor, cause the at least one processor to compute the expectation value of the operator by averaging at least some of the plurality of measurement outcomes.

19. The system of claim 18, wherein the computer program instructions further comprise computer program instructions which, when executed by the at least one processor, cause the at least one processor to decompose the first operator into a decomposition of the plurality of component operators.

20. The system of claim 19, whereby decomposing the first operator into the plurality of component operators comprises decomposing the first operator into a linear combination of orbital-rotated diagonal operators.

21. The system of claim 19, wherein decomposing the first operator into the linear combination of orbital-rotated diagonal operators comprises choosing orbital rotations of the decomposition so as to minimize a depth of the measurement module.

22. The system of claim 19, wherein the first operator comprises a two-body fermionic Hamiltonian, and wherein decomposing the first operator into the plurality of component operators comprises decomposing the first operator into the plurality of component operators using a low-rank decomposition method.

23. The system of claim 19, wherein decomposing the first operator comprises decomposing a first part of the first operator using a linear combination of orbital-rotated diagonal operators and decomposing a second part of the first operator using a method other than a linear combination of orbital-rotated diagonal operators.

24. The system of claim 18, wherein the measurement module further comprises means for applying a corresponding orbital rotation for each component operator.

25. The system of claim 18, wherein the computer program instructions further comprise computer program instructions which, when executed by the at least one processor, cause the at least one processor to compute a plurality of component operator expectation values based on the plurality of measurement outcomes.

26. The system of claim 25, wherein computing the expectation value of the operator comprises averaging all of the plurality of component operator expectation values.

27. The system of claim 25, wherein computing the expectation value of the operator comprises averaging a proper subset of the plurality of component operator expectation values.

28. The system of claim 18, wherein averaging the at least some of the plurality of measurement outcomes comprises computing a weighted average of the at least some of the plurality of measurement outcomes.

29. The system of claim 18, wherein the first operator comprises a Hamiltonian operator.

30. The system of claim 18, wherein the first operator comprises a sum of a Hamiltonian operator and a penalty operator.

31. The system of claim 30, wherein the penalty operator enforces particle number symmetry.

32. The system of claim 30, wherein the penalty operator enforces spin symmetry.

33. The system of claim 30, wherein the penalty operator enforces orthogonality with respect to another state.

34. The system of claim 18, wherein the computer program instructions further comprise computer program instructions which, when executed by the at least one processor, cause the at least one processor to estimate excited state energies of the first operator.

35. A method for computing an expectation value of a first operator more efficiently than Pauli-based grouping, the first operator comprising a plurality of component operators, wherein at least one of the plurality of component operators is not a product of Pauli operators, the method performed by a classical computer comprising at least one processor and at least one non-transitory computer-readable medium comprising computer program instructions executable by the at least one processor to perform the method, the method comprising:
1) computing the expectation value of the first operator, comprising:
(a) simulating a quantum computer measurement module to make a simulated quantum measurement of at least one of the plurality of component operators, to produce a plurality of measurement outcomes of the at least one of the plurality of component operators; and
(b) computing the expectation value of the first operator by averaging at least some of the plurality of measurement outcomes.

36. The method of claim 35, wherein (b) is performed using a Hartree Fock state.

37. The method of claim 35, wherein (b) is performed using Moller-Plesset perturbation theory.

38. A system for computing an expectation value of a first operator more efficiently than Pauli-based grouping, the first operator comprising a plurality of component operators, wherein at least one of the plurality of component operators is not a product of Pauli operators, the system comprising at least one non-transitory computer-readable medium comprising computer program instructions executable by at least one processor to perform a method, the method comprising:
1) computing the expectation value of the first operator, comprising:
(a) simulating a quantum computer measurement module to make a simulated quantum measurement of at least one of the plurality of component operators, to produce a plurality of measurement outcomes of the at least one of the plurality of component operators; and
(b) computing the expectation value of the first operator by averaging at least some of the plurality of measurement outcomes.

39. The system of claim 38, wherein (b) is performed using a Hartree Fock state.

40. The system of claim 40, wherein (b) is performed using Moller-Plesset perturbation theory.
